(19) United States
(12) Patent Application Publication
(10) Pub. No.: US 2019/0043735 A1
(43) Pub. Date: Feb. 7, 2019

(54) METHOD FOR MANUFACTURING SEMICONDUCTOR PACKAGE AND METHOD FOR CUTTING Cu ALLOY

(71) Applicant: Murata Manufacturing Co., Ltd., Nagaokakyo-shi (JP)

(72) Inventor: Seitaro Washizuka, Nagaokakyo-shi (JP)

(21) Appl. No.: 16/157,295

(22) Filed: Oct. 11, 2018

Related U.S. Application Data
(63) Continuation of application No. PCT/JP2017/000475, filed on Jan. 10, 2017.

(30) Foreign Application Priority Data
Apr. 15, 2016 (JP) 2016-082240

(51) Int. Cl. H01L 21/48; B23K 1/00; C22C 9/06; B29C 70/68; H01L 21/56; H01L 23/00

(52) U.S. Cl. CPC H01L 21/4842; B23K 1/0016; C22C 9/06; B29C 70/68; B23K 2101/40; H01L 21/565; H01L 24/32; H01L 24/83; H01L 21/4825

(57) ABSTRACT

A method for manufacturing a semiconductor package by preparing a lead frame including a to-be-cut portion containing a Cu alloy; applying a joining material including Sn or a Sn alloy to the to-be-cut portion; heating the to-be-cut portion so as to react the Sn or Sn alloy and the Cu alloy so as to form an intermetallic compound having a void therein; and cutting the to-be-cut portion together with the intermetallic compound.

### CROSS REFERENCE TO RELATED APPLICATIONS

The present application is a continuation of International application No. PCT/JP2017/000475, filed Jan. 10, 2017, which claims priority to Japanese Patent Application No. 2016-082240, filed Apr. 15, 2016, the entire contents of each of which are incorporated herein by reference.

### FIELD OF THE INVENTION

The present invention relates to a method for manufacturing a semiconductor package and a method for cutting a Cu alloy.

### BACKGROUND OF THE INVENTION

In the process for manufacturing a semiconductor package with the use of a lead frame, electronic components such as semiconductor chips are mounted on a thin metal plate, and then cut into pieces.

Heretofore, as a method for facilitating the cutting into pieces, there has been known a method of applying V groove processing in advance to a site where a lead frame is to be cut with the use of a dicer or the like, for example, as described in Patent Document 1. In addition, as a method of cutting the lead frame, punching by pressing is known, and for example, after placing a resin-sealed semiconductor package on a lower die of a press die, the upper die of the press die is lowered. Thus, punching is performed with the upper die punch and the lower die, thereby cutting the lead frame.

Patent Document 1: Japanese Patent Application Laid-Open No. 2007-189150

### SUMMARY OF THE INVENTION

The method described in Patent Document 1 takes time and effort to perform the V groove processing. In addition, if shavings generated during the V groove processing adhere to parts where electronic components are to be mounted, there is a possibility of causing problems of defective joining and short-circuit defects.

Furthermore, if a step of mounting an electronic component is performed with the use of a lead frame with a V groove formed therein, the lead frame may unintentionally deform with the V groove as a starting point. In addition, when the thickness of the lead frame is small, the V-groove formation itself becomes difficult, and cutting at intended positions may be impossible in some cases. On the other hand, when a lead frame is cut without providing any V groove, burr or sag may be generated at the cut surface.

It is to be noted that in this specification, the burr means a protrusion that is generated on the lower side of the cut surface, and the sag means a part where the upper side of the cut surface is rounded by the pressure of the cutting blade.

The present invention has been made to solve the problems mentioned above, and an object of the present invention is to manufacture a semiconductor package while preventing burr and sag from being caused at the cut surface in the cutting of a lead frame.

In order to achieve the object mentioned above, a method for manufacturing a semiconductor package according to an aspect of the present invention includes: preparing a lead frame including a to-be-cut portion made of a Cu alloy; applying a joining material including Sn or a Sn alloy to the to-be-cut portion; heating the to-be-cut portion so as to react the Sn or Sn alloy and the Cu alloy to form an intermetallic compound having a void therein; and cutting the to-be-cut portion together with the intermetallic compound.

In the method for manufacturing a semiconductor package according to another aspect of the present invention, the to-be-cut portion of the lead frame is also made of a Cu alloy, and is heated with a joining material including Sn or a Sn alloy applied to the to-be-cut portion.

The heating causes the Sn or Sn alloy and the Cu alloy to react to form an intermetallic compound (for example, (Cu,Ni)₆Sn₅), which thereby firmly joins the intermetallic compound and the to-be-cut portion. However, a void (voids) is(are) produced in the formation of the intermetallic compound. In addition, the formed intermetallic compound is a fragile member with reduced ductility.

When a force for cutting is applied to the intermetallic compound firmly joined to the to-be-cut portion, cracks develop without any deformation in the intermetallic compound. The Cu alloy joined to the intermetallic compound, which is originally a ductile material, fails to extend because the alloy is firmly joined to the intermetallic compound, and thereby leading to fracture of the to-be-cut portion. As a result, burr and sag are prevented from being caused at the cut surface of the Cu alloy of the to-be-cut portion, thereby making it possible to obtain a clean cut surface.

In addition, according to this method, there is no need to provide any V groove in the to-be-cut portion, and cutting can be thus performed favorably even when the lead frame is small in thickness. In addition, there is no problem caused by shavings generated in the V groove processing.

In the method for manufacturing a semiconductor package according to another aspect of the present invention, preferably, the lead frame is provided with a mount portion comprising a Cu alloy, and the method further includes the steps of: applying a joining material including Sn or a Sn alloy to the mount portion, mounting an electronic component to the mount portion; and heating the mount portion while applying a pressure to the electronic component so as to react the Sn or Sn alloy the Cu alloy of the mount portion to form an intermetallic compound containing little or no voids.

According to the method above, the electronic component and the mount portion can be joined with the intermetallic compound. The intermetallic compound formed from the Cu alloy and the Sn or Sn alloy has a high melting point, thus making it possible to join the electronic component and the mount portion by a joint with excellent heat resistance. In addition, when the mount portion is heated while applying a pressure to the electronic component, any voids generated with the formation of the intermetallic compound are pushed out by the applying of the pressure, and a dense intermetallic compound is then formed. Therefore, firm joining is achieved.

In the method for manufacturing a semiconductor package according to an aspect of the present invention, the to-be-cut portion is preferably heated simultaneously with heating the mount portion.

The to-be-cut portion is heated simultaneously with heating the mount portion, thereby allowing for the reactions of forming intermetallic compounds in the mount portion and the to-be-cut portion in the same process.

A dense intermetallic compound with a strong joining force can be formed in the mount portion heated while applying the pressure, and a brittle intermetallic compound comprising a void can be formed in the to-be-cut portion heated without applying any pressure.

In the method for manufacturing a semiconductor package according to the present invention, the electronic component is preferably a semiconductor chip.

In the method for manufacturing a semiconductor package according to the present invention, the Cu alloy is preferably a Cu—Ni alloy or a Cu—Mn alloy. Further, a Cu—Ni alloy that has a Ni proportion of 3% to 15% by weight is more preferred.

Cu—Ni alloys or Cu—Mn alloys can react quickly with Sn or Sn alloys to form intermetallic compounds. The Cu—Ni alloy with a Ni proportion of 3% to 15% by weight forms the intermetallic compound more reliably.

A method for cutting a Cu alloy according to as aspect of the present invention includes: applying a joining material including Sn or a Sn alloy to a to-be-cut portion made of a Cu alloy; heating the to-be-cut portion so as to react the Sn or Sn alloy and the Cu alloy to form an intermetallic compound having a void therein; and cutting the to-be-cut portion together with the intermetallic compound.

The to-be-cut portion made of the Cu alloy is reacted with the Sn or Sn alloy to form an intermetallic compound having a void therein, and the to-be-cut portion is cut along with the intermetallic compound, thereby preventing burr and sag from being caused at the cut surface of the Cu alloy constituting the to-be-cut portion, and thus making it possible to obtain a clean cut surface.

This cutting method can be suitably used as a method for cutting a material made of a Cu alloy, regardless of the shape of the material.

According to aspect of the present invention, a semiconductor package can be manufactured while burr and sag are prevented from being caused at the cut surface in cutting a lead frame. In addition, a method for cutting a Cu alloy can be provided which is capable of cutting a material made of a Cu alloy while burr and sag are prevented from being caused at the cut surface.

### BRIEF EXPLANATION OF THE DRAWINGS

FIG. 1 is a top view illustrating an example of a lead frame.

FIGS. 2A to 2D are cross-sectional views schematically illustrating an example of a method for manufacturing a semiconductor package according to the present invention.

FIGS. 3A to 3D are cross-sectional views schematically illustrating another example of a method for manufacturing a semiconductor package according to the present invention.

FIG. 4A is a cross-sectional observation photograph of a mounting portion by a metallurgical microscope, and FIG. 4B is a cross-sectional observation photograph by a metallurgical microscope before cutting a portion to be cut.

FIG. 5 is a cross-sectional observation photograph through a metallurgical microscope of a cut part according to Example 1 after the cutting.

FIG. 6 is a cross-sectional observation photograph through a metallurgical microscope of a cut part according to Comparative Example 1 after the cutting.

### DETAILED DESCRIPTION OF THE INVENTION

A method for manufacturing a semiconductor package and a method for cutting a Cu alloy according to the present invention will be described below.

However, the present invention is not to be considered limited to the following configurations, but can be applied with changes appropriately made without changing the scope of the present invention.

It is to be noted that the present invention also encompasses combinations of two or more individual desirable configurations according to the present invention as described below.

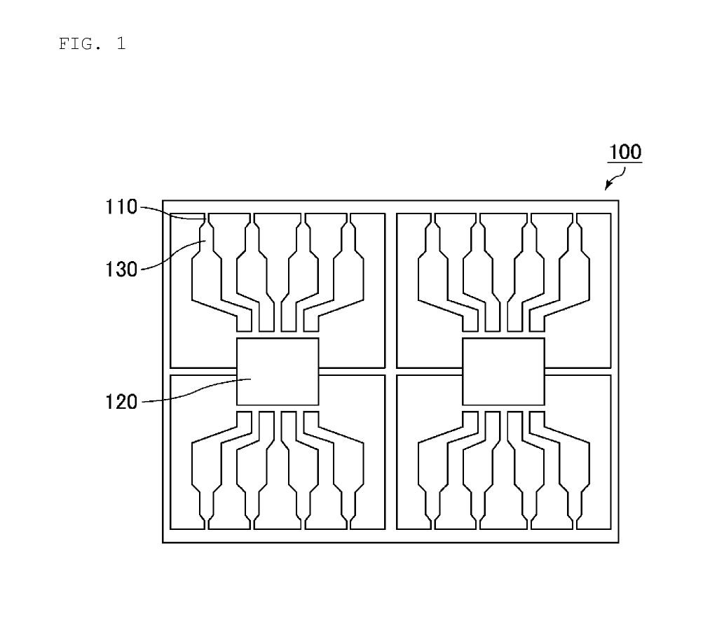

FIG. 1 is a top view illustrating an example of a lead frame.

In the method for manufacturing a semiconductor package according to the present invention, a lead frame including a to-be-cut portion made of a Cu alloy is prepared.

The lead frame 100 is provided with a mount portion 120 which is a part for mounting an electronic component, and an end of each lead 130 is provided with a to-be-cut portion 110 which is a part to be cut for dividing into individual pieces. The material of the to-be-cut portion 110 is a Cu alloy.

Examples of the Cu alloy include, for example, a Cu—Ni alloy, a Cu—Mn alloy, a Cu—Al alloy, or a Cu—Cr alloy. Among these alloys, Cu—Ni alloys or Cu—Mn alloys are preferred.

The Cu—Ni alloy is preferably a Cu—Ni alloy that has a Ni proportion of 3% to 30% by weight, and examples of the Cu—Ni alloy include, for example Cu-3Ni, Cu-5Ni, Cu-10Ni, Cu-15Ni, Cu-20Ni, Cu-25Ni, or Cu-30Ni. Further, a Cu—Ni alloy that has a Ni proportion of 3% to 15% by weight is more preferred. The examples of the Cu—Ni alloy also include an alloy containing a third component, such as a Cu—Ni—Co alloy, a Cu—Ni—Fe alloy, a Cu—Ni—Si alloy, and a Cu—Ni—P alloy.

The Cu—Mn alloy is preferably a Cu—Mn alloy that has a Mn proportion of 5% by weight or more and 30% by weight or less, and examples of the Cu—Mn alloy include, for example, Cu-5Mn, Cu-10Mn, Cu-15Mn, Cu-20Mn, Cu-25Mn, or Cu-30Mn.

The Cu—Al alloy is preferably a Cu—Al alloy that has an Al proportion of 5% by weight or more and 10% by weight or less, and examples of the Cu—Al alloy include, for example, Cu-5Al or Cu-10Al.

The Cu—Cr alloy is preferably a Cu—Cr alloy that has a Cr proportion of 5% by weight or more and 10% by weight or less, and examples of the Cu—Cr alloy include, for example, Cu-5Cr or Cu-10Cr.

Further, the Cu alloy may contain Mn and Ni at the same time, such as a Cu—Mn—Ni, and may contain a third component such as P.

In the above notation, for example, “Cu-3Ni” indicates an alloy containing 3% by weight of Ni and Cu as the rest. The same applies to Mn.

The material constituting the lead frame may be entirely a Cu alloy, or the to-be-cut material may be a Cu alloy, whereas the other part may be another material. When an intermetallic compound is also formed in the mount portion as described later, the mount portion is preferably also made of a Cu alloy.

In addition, the position of the to-be-cut portion provided in the lead frame, which is a site to be cut in the present invention, is not limited to the end of each lead, but may be any site that is cut in the manufacture of the semiconductor package with the use of the lead frame. For example, the site may be an end of a suspension lead (a lead that supports a die pad) or a dam bar (a connection that creates a connection between leads).

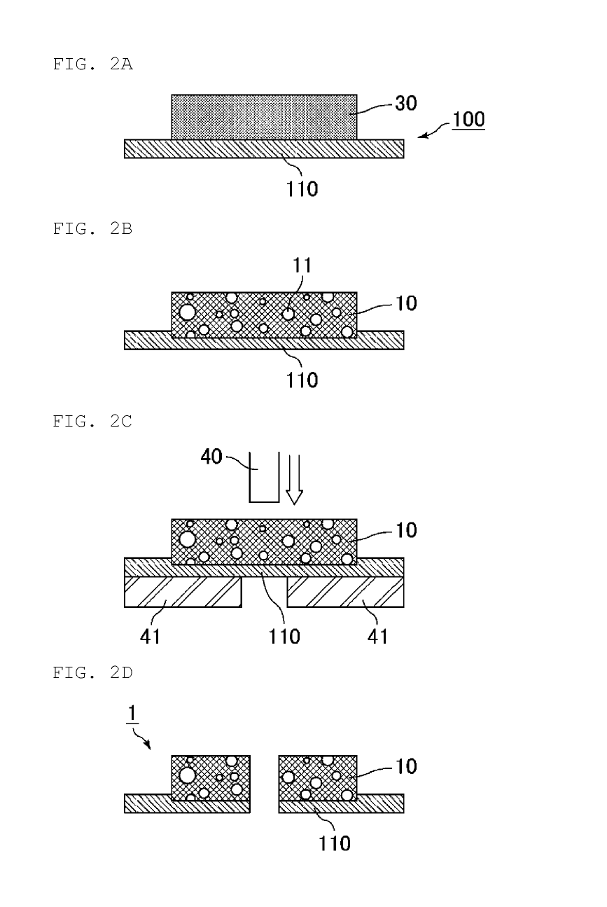

FIGS. 2A to 2D are cross-sectional views schematically illustrating an example of a method for manufacturing a semiconductor package according to the present invention. FIGS. 2A to 2D are sectional views schematically illustrating only the periphery of the to-be-cut portion 110 of the lead frame 100.

First, as shown in FIG. 2A, a joining material 30 including Sn or a Sn alloy is applied to the to-be-cut portion 110.

Examples of the Sn or Sn alloy include, a single element Sn, or an alloy containing Sn and at least one selected from the group consisting of Cu, Ni, Ag, Au, Sb, Zn, Bi, In, Ge, Al, Co, Mn, Fe, Cr, Mg, Mn, Pd, Si, Sr, Te, and P. Among the foregoing examples, Sn, Sn-3Ag-0.5Cu, Sn-3.5Ag, Sn-0.75Cu, Sn-58Bi, Sn-0.7Cu-0.05Ni, Sn-5Sb, Sn-2Ag-0.5Cu-2Bi, Sn-57Bi-1Ag, Sn-3.5Ag-0.5Bi-8In, Sn-9Zn, or Sn-8Zn-3Bi is preferred.

In the above notation, for example, “Sn-3Ag-0.5Cu” indicates an alloy containing 3% by weight of Ag and 0.5% by weight of Cu, and containing Sn as the rest.

The joining material containing Sn or a Sn alloy is preferably a paste containing Sn or a Sn alloy, and as the paste, a commercially available solder paste containing Sn or a Sn alloy and a flux can be used. In addition, the metal component included in the paste is not necessarily only Sn or a Sn alloy, but may contain a metal component such as Cu, a Cu alloy, Ni, a Ni alloy, Ag, or an Ag alloy, with Sn or a Sn alloy as a main constituent.

Examples of the method for applying the joining material to the to-be-cut portion include, for example, screen printing, and application with a dispenser.

Next, as shown in FIG. 2B, the to-be-cut portion is heated. When the heating causes temperature to reach or exceed the melting point of the Sn or Sn alloy included in the joining material, the Sn or Sn alloy is melted. When the heating is further continued, the Sn or Sn alloy and the Cu alloy (for example, a Cu—Ni alloy) constituting the to-be-cut portion 110 react to produce an intermetallic compound 10 (for example, (Cu,Ni)₆Sn₅).

This heating is preferably performed without applying any pressure to the to-be-cut portion and the joining material, and with the reaction of producing the intermetallic compound 10, a void 11 is formed in the intermetallic compound 10. The intermetallic compound 10 with the void 11 therein becomes a fragile member with lowered ductility.

Then, the intermetallic compound 10 and the to-be-cut portion 110 are firmly joined together. Increasing the rate of temperature rise during the heating is preferable, because an intermetallic compound comprising a void is likely to be formed. The rate of temperature rise is preferably 5° C./s or higher, more preferably 8° C./s or higher.

The production of an intermetallic compound can be confirmed in a simplified manner by observing a cross section including the to-be-cut portion with a metallurgical microscope. Specifically, the production of an intermetallic compound such as (Cu,Ni)₆Sn₅ can be confirmed through composition analysis by energy dispersive X-ray analysis (EDX) or the like and crystal structure analysis by micro X-ray diffraction or the like.

Next, as shown in FIG. 2C, a punch 40 is placed over the intermetallic compound 10, a die 41 is placed under the to-be-cut portion 110, and the to-be-cut portion 110 is cut along with the intermetallic compound 10 by punching.

Cracks develop without any deformation in the intermetallic compound 10 to which a force for cutting is applied by the punch 40. The Cu alloy constituting the to-be-cut portion 110, which is originally a ductile material, fails to extend because the alloy is firmly joined to the intermetallic compound 10 and which thereby leads to fracture of the to-be-cut portion 110. As a result, burr and sag are prevented from being caused at the cut surface of the Cu alloy constituting the to-be-cut portion 110, thereby making it possible to obtain a clean cut surface.

FIG. 2D shows a cut surface of the semiconductor package 1 obtained after cutting the to-be-cut portion. No burr or sag is caused at the cut surface, and the intermetallic compound 10 remains at each end of the cut part.

It is to be noted that the cutting method is not to be considered limited to punching, and examples of the method include cutting with a dicing machine or an ultrasonic cutter.

Next, an embodiment including a step of mounting an electronic component on a mount portion will be described as another embodiment of the present invention.

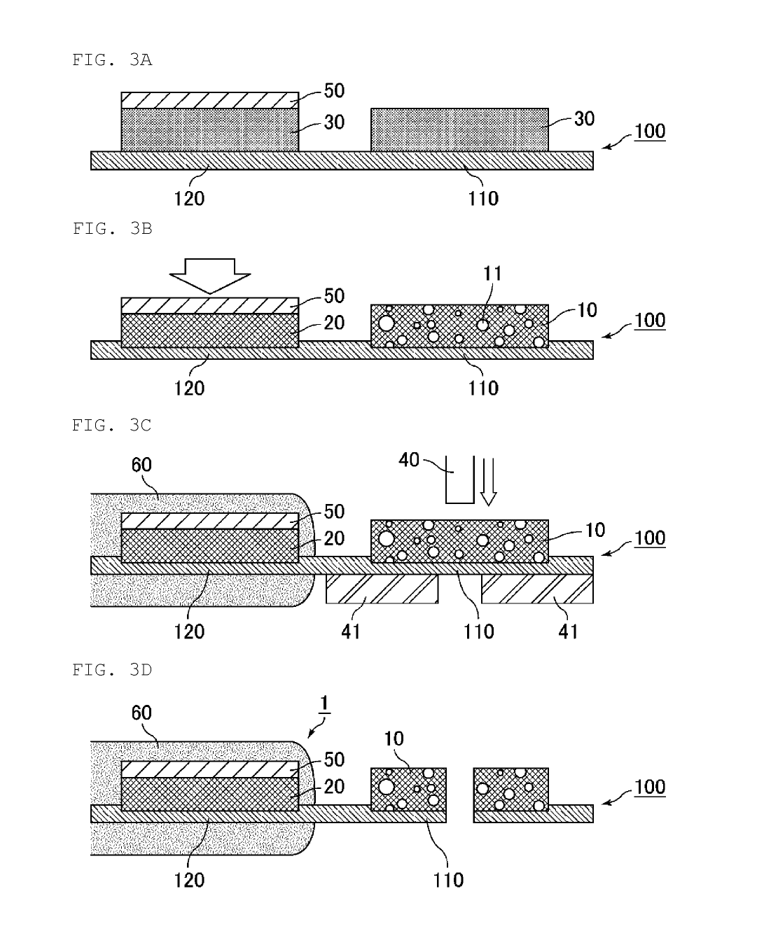

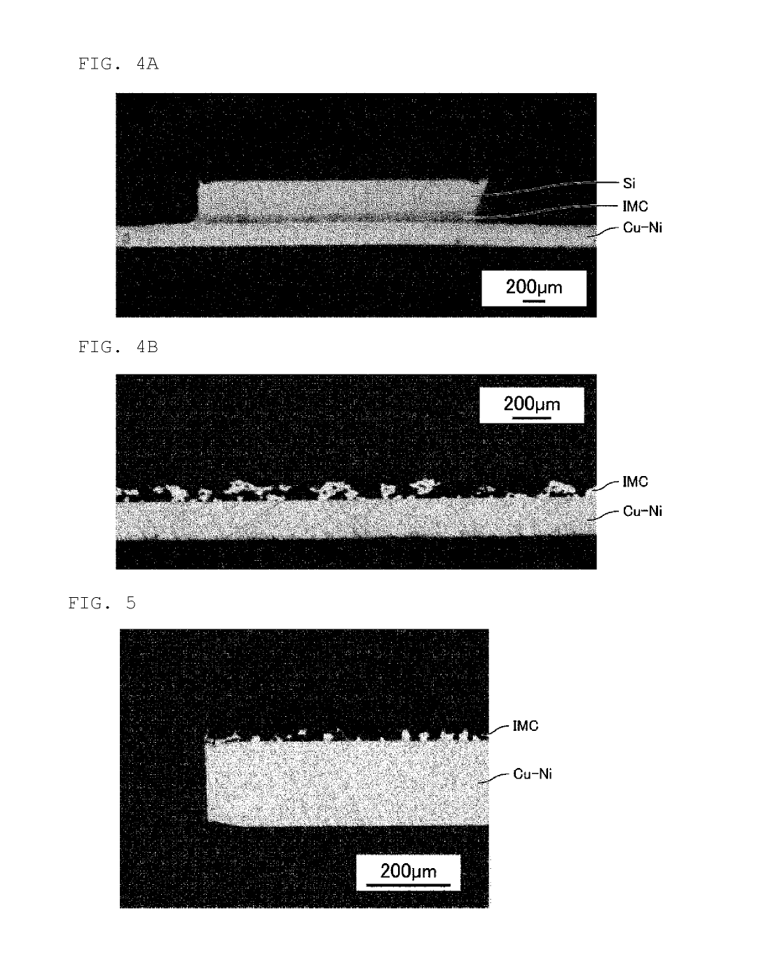

FIGS. 3A to 3D are cross-sectional views schematically illustrating another example of a method for manufacturing a semiconductor package according to the present invention. FIGS. 3A to 3D are cross-sectional views schematically illustrating only the periphery of a mount portion 120 of a lead frame 100 and the periphery of a to-be-cut portion 110 thereof. For the lead frame for use in the present embodiment, both the mount portion and the to-be-cut portion are formed from a Cu alloy. The whole lead frame may be a Cu alloy, and as long as the mount portion and the to-be-cut portion are Cu alloys, the other part may be any other material. The Cu alloy constituting the mount portion and the Cu alloy constituting the to-be-cut portion may have different compositions, but the whole lead frame is preferably a Cu alloy that has the same composition. Preferred examples of the Cu alloy constituting the mount portion are the same as those given as examples of the Cu alloy constituting the to-be-cut portion, and detailed descriptions thereof will be thus omitted.

First, as shown in FIG. 3A, a joining material 30 containing Sn or a Sn alloy is applied to the mount portion 120 and the to-be-cut portion 110. The same joining material may be applied to the mount portion 120 and the to-be-cut portion 110. or different joining materials may be applied thereto.

Examples of the method for applying the joining material to the mount portion and the to-be-cut portion include, for example, methods such as screen printing, and application with a dispenser. It is preferable to perform the joining material application simultaneously to the mount portion and the to-be-cut portion.

On the joining material 30 on the mount portion 120, an electronic component 50 is mounted.

Examples of the electronic component include a semiconductor chip (IGBT (Insulated Gate Bipolar Transistor), a MOSFET (Metal Oxide Semiconductor Field Effect Transistor), a Schottky barrier diode, an LED, etc.), a capacitor, an inductor, a thermistor, a resistor, a varistor, and other chip-shaped laminated filters, among which the semiconductor chip is preferred.

The present invention is particularly suitable for application to a semiconductor package of a type with a semiconductor chip die-bonded.

A plating layer made of Au, Ag, Ni, Pd, Cu, or an alloy containing these metals may be formed on the surface of an electrode with which the joining material is brought into contact in the electronic component. A plating layer composed of multiple layers may be formed, such as a Ni/Au plating layer with Ni as a first layer and Au as a second layer from the electrode side, or a Ni/Pd/Au plating layer with Ni as a first layer, Pd as a second layer, and Au as a third layer from the electrode side.

In addition, a part with which the joining material is brought into contact in the mount portion may serve as an electrode formed for the mount portion. A plating layer made of Au, Ag, Ni, Pd, Cu, or an alloy containing these metals may also be formed on the surface of the foregoing electrode. A plating layer composed of multiple layers may be formed, such as a Ni/Au plating layer or a Ni/Pd/Au plating layer. In addition, a plating layer made of Sn or a Sn alloy may be formed.

It is to be noted that the electrode of the electronic component and the electrode of the mounting part are omitted in FIGS. 3A to 3D.

Next, as shown in FIG. 3B, the mount portion 120 is heated while applying a pressure to the electronic component 50.

When the heating causes temperature to reach or exceed the melting point of the Sn or Sn alloy included in the joining material, the Sn or Sn alloy is melted. When the heating is further continued, the Sn or Sn alloy and the Cu alloy (for example, a Cu—Ni alloy) constituting the mount portion 120 react to produce an intermetallic compound 20 (for example, (Cu,Ni)₆Sn₅).

Heating the mount portion while applying a pressure to the electronic component pushes air to the outside of the intermetallic compound, thus producing a dense intermetallic compound having little or no voids. The mount portion 120 and the electronic component 50 are firmly joined by the dense intermetallic compound 20. The intermetallic compound has a higher melting point than Sn or a Sn alloy, and thus allows for a joint with high heat resistance.

It is preferable to heat the mount portion 120 while applying a pressure to the electronic component 50, and simultaneously heat the to-be-cut portion 110. The intermetallic compound 10 comprising a void 11 is formed by heating the to-be-cut portion 110 without applying any pressure to the to-be-cut portion 110 and the joining material 30. As described above, the intermetallic compound containing a void serves as a fragile member with lowered ductility.

Simultaneously heating the mount portion and the to-be-cut portion makes it possible to mount the electronic component on the lead frame simultaneously with the formation of a brittle intermetallic compound for facilitating the cutting of the to-be-cut portion, and the step for facilitating the cutting of the to-be-cut portion is thus a more efficient step as compared with a method of applying V groove processing to the to-be-cut portion, or the like.

FIGS. 3C and 3D illustrate steps of cutting the to-be-cut portion 110 together with the intermetallic compound 10, as in the steps shown in FIGS. 2C and 2D.

It is preferable to cut the to-be-cut portion after molding the electronic component 50 with a resin 60. The to-be-cut portion 110 is located outside the resin 60.

Although not shown in the drawings, the electronic component 50 may be connected to the electrode of the lead frame by wire bonding or the like.

The method mentioned above makes it possible to join the electronic component firmly to the mount portion with the intermetallic compound, and to cut the to-be-cut portion without causing burr or sag at the cut surface, thereby manufacturing the semiconductor package 1.

Next, a method for cutting a Cu alloy according to the present invention will be described.

The method for cutting a Cu alloy according to the present invention is a method in which a Cu alloy constituting a to-be-cut portion is reacted with Sn or a Sn alloy to form an intermetallic compound comprising a void, and the to-be-cut portion is cut along with the intermetallic compound, thereby cutting the Cu alloy. As long as the material to be cut is a Cu alloy, the method can be applied not only to the to-be-cut portion of the lead frame, and the shape of the material is not limited.

The materials described in the above-mentioned method for manufacturing the semiconductor package according to the present invention can be suitably used as the Cu alloy and the Sn or Sn alloy.

Examples of the form of the Cu alloy include a round wire, a rectangular wire, a braided wire, a rod material, a plate material, a foil, a circular tube, and a rectangular tube.

The cutting method may be determined depending on the shape of the Cu alloy to be cut and the like, and punching, shirring, dicing, or the like can be suitably used.

In addition, the method for cutting the Cu alloy according to the present invention includes drilling into a member in addition to the cutting for separating the member into two or more parts. By forming an intermetallic compound at a site that is brought into contact with a punch for drilling, and punching out the to-be-punched part together with the intermetallic compound, a hole without burr or sag can be formed in the hole wall.

### EXAMPLES

Examples in which the method for manufacturing a semiconductor package according to the present invention is more specifically disclosed will be described below. It is be noted that the present invention is not to be considered limited to only these examples.

### Example 1

(1) Solder Paste Printing

Onto a 200 μm-thick lead frame made of Cu-10Ni, a commercially available solder paste (SAC 305: Sn-3Ag-0.5Cu) was applied by screen printing.

The solder paste for a 5 mm square and 5 mm×1 mm was applied by the printing at a time respectively onto the mount portion on which a Si chip was to be mounted, and onto the to-be-cut portion. The thickness of the metal plate for screen printing was 50 μm.

(2) Si Chip Mounting

The 5 mm-square Si chip of 300 μm in thickness was mounted on the solder paste applied to the mount portion. Further, the mounting surface of the Si chip was subjected to an Au plating treatment.

(3) Heating

The lead frame with the Si chip mounted was heated at 260° C. for 5 minutes through temperature rise at 260° C./30 seconds in a nitrogen atmosphere. The mount portion was heated while applying a pressure of 10 MPa thereto.

The thickness of the intermetallic compound formed on the to-be-cut portion after the heating was measured with a metallurgical microscope, and found to be 20 μm.

(4) Cutting

A punch and a die were set for the to-be-cut portion, and the to-be-cut portion was cut by punching.

### Examples 2 to 4

The respective steps were carried out in the same manner as in Example 1 except for the change of the thickness of the metal plate for the screen printing and the change of the applied thickness of the solder paste. The thicknesses of the intermetallic compounds formed on the to-be-cut portions after the heating are shown in Table 1.

### Examples 5 to 7

The respective steps were carried out in the same manner as in Example 4 except that the material of the lead frame was changed as shown in Table 1.

### Comparative Example 1

The respective steps were carried out in the same manner as in Example 1 without applying the solder paste to the to-be-cut portion.

### Comparative Example 2

The respective steps were carried out in the same manner as in Example 1, except that the material of the lead frame was Cu, and that the solder paste was not applied to the to-be-cut portion.

### Comparative Example 3

The respective steps were carried out in the same manner as in Example 4 except that the material of the lead frame was Cu.

### Cross Section Observation

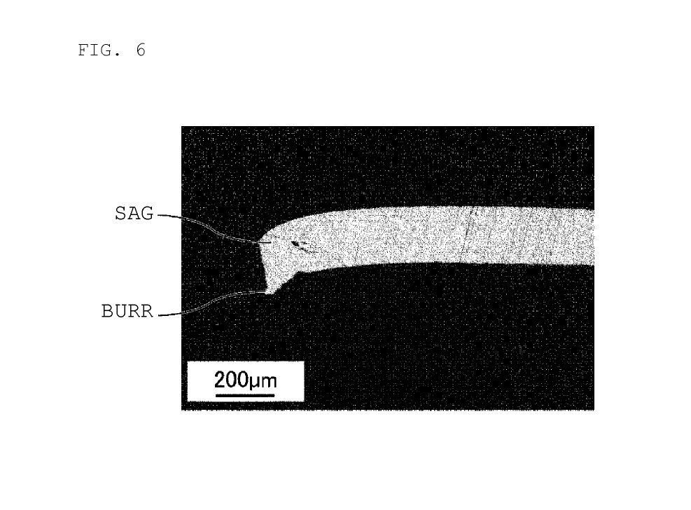

FIG. 4A is a cross-sectional observation photograph of the mount portion through a metallurgical microscope, and FIG. 4B is a cross-sectional observation photograph of the to-be-cut portion before the cutting through a metallurgical microscope. Si refers to a Si chip, Cu—Ni refers to a lead frame, and IMC refers to an intermetallic compound. These photographs both come from Example 4.

As shown in FIG. 4A, it is determined that a dense intermetallic compound (IMC) is formed between the Si chip and the lead frame for the mount portion, whereas an intermetallic compound (IMC) comprising a void is formed on the lead frame for the to-be-cut portion.

FIG. 5 is a cross-sectional observation photograph of the to-be-cut portion according to Example 1 after the cutting through a metallurgical microscope, and FIG. 6 is a cross-sectional observation photograph of the to-be-cut portion according to Comparative Example 1 after the cutting through a metallurgical microscope.

It is determined that the to-be-cut portion according to Example 1 has a clean cut surface without any burr or sag, whereas the to-be-cut portion according to Comparative Example 1 has burr and sag generated.

Table 1 summarizes the materials of the lead frames used according to the respective examples and comparative examples, the solder paste, the thicknesses of the intermetallic compounds formed on the to-be-cut portions after the heating, and the observation results of the cut surfaces.

The observation results of the cut surfaces are shown as follows.

◯: a clean cut surface without burr or sag was obtained.

×: burr or sag was generated at the cut surface, or there was a site where it was not possible to cut the to-be-cut portion.

TABLE 1

| | | | Cut Part IMC | |
|---|---|---|---|---|
| | Lead Frame | Solder | Thickness | Observ. |
| | Material | Paste | (μm)*¹ | Result |
| Example 1 | Cu—10Ni | SAC305 | 20 | ◯ |
| Example 2 | Cu—10Ni | SAC305 | 50 | ◯ |
| Example 3 | Cu—10Ni | SAC305 | 80 | ◯ |
| Example 4 | Cu—10Ni | SAC305 | 100 | ◯ |
| Example 5 | Cu—4Ni | SAC305 | 100 | ◯ |
| Example 6 | Cu—3Ni—4Co | SAC305 | 100 | ◯ |
| Example 7 | Cu—15Ni | SAC305 | 100 | ◯ |
| Comp. Ex. 1 | Cu—10Ni | No | | X |
| Comp. Ex. 2 | Cu | No | | X |
| Comp. Ex. 3 | Cu | SAC305 | No IMC*² | X |

*¹The cut part IMC thickness means the thickness of an intermetallic compound formed on the cut part after the heating.
*²Comparative Example 3 has no IMC formed, and has a remaining metallic component containing Sn.

From Table 1, it was confirmed that Examples 1 to 7 provide clean cut surfaces without burr or sag.

According to Comparative Examples 1 and 2, the solder paste is not applied to the to-be-cut portions, and the Cu-10Ni alloy or Cu is thus cut directly. There were burr and sag generated by cutting, because the Cu-10Ni alloy and Cu are ductile materials.

According to Comparative Example 3, because the material of the lead frame is Cu, even when the solder paste is applied and heated, no intermetallic compound is generated, and the metallic component containing Sn remains on the lead frame. There were burr or sag generated by cutting, because the metallic component makes no contribution to improvement in cutting performance.

### DESCRIPTION OF REFERENCE SYMBOLS

1: Semiconductor package

10: Intermetallic compound (intermetallic compound comprising a void)

11: Void

20: Intermetallic compound (dense intermetallic compound)

30: Joining material

40: Punch

41: Die

50: Electronic component

60: Resin

100: Lead frame

110: To-be-cut portion

120: Mount portion

130: Lead wire

1. A method for manufacturing a semiconductor package, the method comprising:
preparing a lead frame having a to-be-cut portion, at least the to-be-cut portion comprising a Cu alloy;
applying a joining material including Sn or a Sn alloy to the to-be-cut portion;
heating the to-be-cut portion so as to react the Sn or the Sn alloy in the joining material and the Cu alloy to produce an intermetallic compound having a void therein; and
cutting the to-be-cut portion together with the intermetallic compound.

2. The method for manufacturing a semiconductor package according to claim 1, wherein the Cu alloy is a first Cu alloy, the joining material is a first joining material, the intermetallic compound is a first intermetallic compound, and the lead frame includes a mount portion comprising a second Cu alloy, the method further comprising:
applying a second joining material including Sn or a Sn alloy on the mount portion;
mounting an electronic component on the second joining material; and
heating the mount portion while applying a pressure to the electronic component so as to react the Sn or the Sn alloy in the second joining material and the second Cu alloy of the mount portion so as to produce a second intermetallic compound.

3. The method for manufacturing a semiconductor package according to claim 2, further comprising molding the electronic component with a resin.

4. The method for manufacturing a semiconductor package according to claim 2, wherein the heating of the to-be-cut portion is performed simultaneously with the heating of the mount portion.

5. The method for manufacturing a semiconductor package according to claim 2, wherein the electronic component is a semiconductor chip.

6. The method for manufacturing a semiconductor package according to claim 1, wherein the Cu alloy is a Cu—Ni alloy, a Cu—Mn alloy, a Cu—Al alloy, or a Cu—Cr alloy.

7. The method for manufacturing a semiconductor package according to claim 1, wherein the Cu alloy is a Cu—Ni alloy or a Cu—Mn alloy.

8. The method for manufacturing a semiconductor package according to claim 1, wherein the Cu alloy is a Cu—Ni alloy that has a Ni proportion of 3% to 15% by weight.

9. The method for manufacturing a semiconductor package according to claim 1, wherein the Cu alloy is a Cu—Ni alloy that has a Ni proportion of 3% to 30% by weight.

10. The method for manufacturing a semiconductor package according to claim 1, wherein the Cu alloy is a Cu—Mn alloy that has a Mn proportion of 5% to 30% by weight.

11. The method for manufacturing a semiconductor package according to claim 1, wherein the Cu alloy is a Cu—Al alloy that has an Al proportion of 5% to 10% by weight.

12. The method for manufacturing a semiconductor package according to claim 1, wherein the Cu alloy is a Cu—Cr alloy that has a Cr proportion of 5% to 10% by weight.

13. The method for manufacturing a semiconductor package according to claim 1, wherein the Sn alloy contains Sn and at least one selected from Cu, Ni, Ag, Au, Sb, Zn, Bi, In, Ge, Al, Co, Mn, Fe, Cr, Mg, Mn, Pd, Si, Sr, Te, and P.

14. The method for manufacturing a semiconductor package according to claim 1, wherein a rate of temperature rise of the heating of the to-be-cut portion is 5° C./s or higher.

15. The method for manufacturing a semiconductor package according to claim 1, wherein a rate of temperature rise of the heating of the to-be-cut portion is 8° C./s or higher.

16. A method for cutting a Cu alloy, the method comprising:
applying a joining material including Sn or a Sn alloy to a to-be-cut portion comprising a Cu alloy;
heating the to-be-cut portion so as to react the Sn or the Sn alloy and the Cu alloy to produce an intermetallic compound having a void therein; and
cutting the to-be-cut portion together with the intermetallic compound.

17. The method for cutting a Cu alloy according to claim 16, wherein the Cu alloy is a Cu—Ni alloy, a Cu—Mn alloy, a Cu—Al alloy, or a Cu—Cr alloy.

18. The method for cutting a Cu alloy according to claim 16, wherein the Sn alloy contains Sn and at least one selected from Cu, Ni, Ag, Au, Sb, Zn, Bi, In, Ge, Al, Co, Mn, Fe, Cr, Mg, Mn, Pd, Si, Sr, Te, and P.

19. The method for cutting a Cu alloy according to claim 16, wherein a rate of temperature rise of the heating of the to-be-cut portion is 5° C./s or higher.

20. The method for cutting a Cu alloy according to claim 16, wherein a rate of temperature rise of the heating of the to-be-cut portion is 8° C./s or higher.
